(19) United States
(12) Patent Application Publication
(10) Pub. No.: US 2015/0323595 A1
(43) Pub. Date: Nov. 12, 2015

(54) SYSTEM FOR REDUCING TEST TIME USING EMBEDDED TEST COMPRESSION CYCLE BALANCING

(71) Applicant: LSI Corporation, San Jose, CA (US)

(72) Inventors: Ajaykumar B. Prajapati, Bangalore (IN); Deepak Agrawal, Bangalore (IN); Hariprasad U. Bhat, Bangalore (IN)

(73) Assignee: LSI Corporation, San Jose, CA (US)

(21) Appl. No.: 14/272,606

(22) Filed: May 8, 2014

(51) Int. Cl. G01R 31/3177

(52) U.S. Cl. CPC G01R 31/3177

(57) ABSTRACT

An apparatus for reducing test time is disclosed. The apparatus includes a processor operable to execute one or more modules to cause the processor to receive operational parameters associated with a first scan chain grouping circuitry and a second scan chain grouping circuitry of an integrated circuit design. The operational parameters include a number of initialization cycles of a first test signal selected for the first scan chain grouping circuitry, a number of initialization cycles of a second test signal selected for the second scan chain grouping circuitry, and a sum for a total number of cycles for the first test signal. The processor also determines a scan chain length for one of the first scan chain grouping circuitry or the second scan chain grouping circuitry based upon the operation parameters such that the total number of cycles of the first signal and the second signal are the same.

### FIELD OF THE INVENTION

The present invention is directed to a system for reducing integrated circuit test time, and more particularly to a system for reducing test time using embedded test compression cycle balancing.

### BACKGROUND

Automatic test pattern generation (ATPG) is used to identify test sequences that can be applied to circuits and/or logic to determine whether the circuits and/or logic function (e.g., behave) correctly. ATPG test patterns are utilized to test semiconductor devices after manufacturing. These testing modes present the test patterns at varying speeds (e.g., clock speeds) to ensure the semiconductor devices function correctly at the respective speed.

### SUMMARY

An apparatus for reducing test time using embedded test compression cycle balancing is disclosed. In one or more embodiments, the apparatus includes a memory and a processor. The processor is operable to execute one or more modules to cause the processor to receive operational parameters associated with a first scan chain grouping circuitry and a second scan chain grouping circuitry of an integrated circuit design. The operational parameters include a characteristic number of initialization cycles of a first test signal selected for the first scan chain grouping circuitry, a characteristic number of initialization cycles of a second test signal selected for the second scan chain grouping circuitry, and a sum for a total number of cycles for the first test signal. The processor also determines a scan chain length for at least one of the first scan chain grouping circuitry or the second scan chain grouping circuitry based upon the operation parameters such that the total number of cycles of the first signal and the second signal are the same.

This Summary is provided to introduce a selection of concepts in a simplified form that are further described below in the Written Description. This Summary is not intended to identify key features or essential features of the claimed subject matter, nor is it intended to be used as an aid in determining the scope of the claimed subject matter.

### BRIEF DESCRIPTION OF THE FIGURES

The Written Description is described with reference to the accompanying figures. The use of the same reference numbers in different instances in the description and the figures may indicate similar or identical items.

FIG. 1 is a block diagram of a system including an automatic testing device (e.g., automatic testing equipment) that is operatively connected to a circuit under test (e.g., integrated circuit device) in accordance with an example embodiment of the present disclosure.

FIG. 2 is a diagrammatic illustration of a system on a chip device in accordance with an example embodiment of the present disclosure.

FIG. 3 is a diagrammatic illustration of a test signal having initialization cycles and internal scan chain shift cycles in accordance with an example embodiment of the present disclosure.

FIG. 4 is a diagrammatic illustration of a conventional system on a chip device having multiple scan chain grouping circuitry, respective scan chain lengths, and corresponding test signals.

FIG. 5 is a diagrammatic illustration of a system on a chip device having multiple scan chain grouping circuitry, respective scan chain lengths, and corresponding test signals in accordance with an example embodiment of the present disclosure.

FIG. 6 is a method diagram for determining a scan chain length for multiple scan chain grouping circuitry for a system on a chip device in accordance with an example embodiment of the present disclosure.

### WRITTEN DESCRIPTION

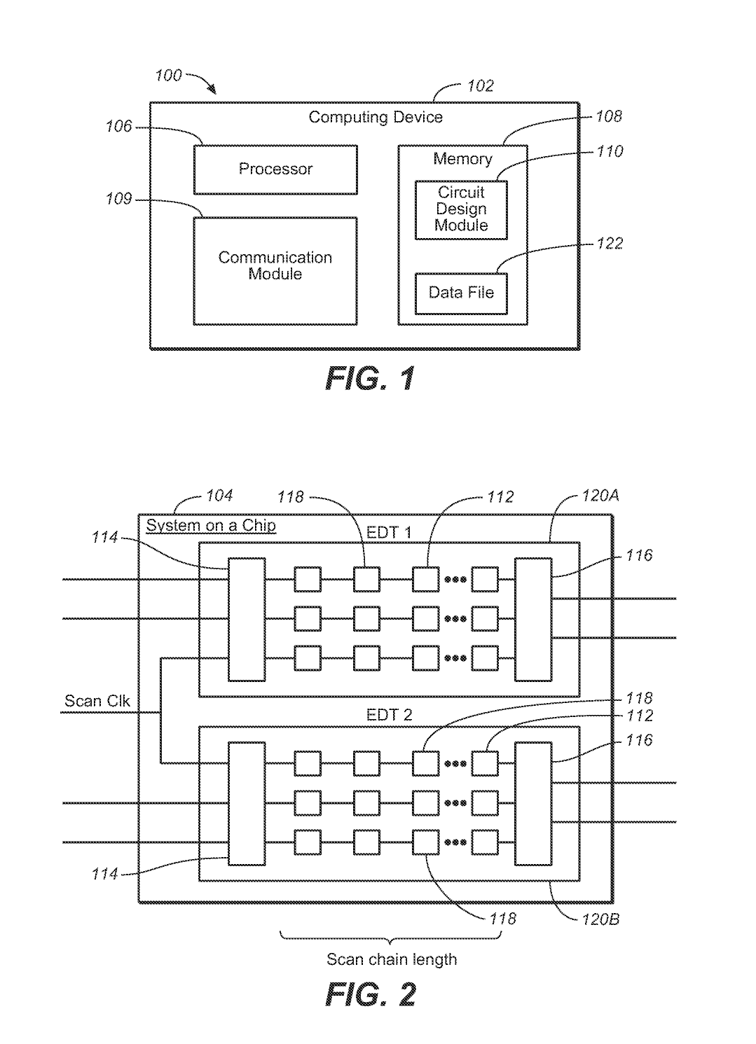

FIG. 1 illustrates a system 100 for test time optimization using embedded test compression (EDT) cycle balancing in accordance with an example embodiment of the present disclosure. As shown, the system 100 includes a computing device 102 configured to design and/or simulate integrated circuit device (e.g., system on a chip (SoC) device 104 designs). The computing device 102 includes a processor 106 and a memory 108.

The processor 106 provides processing functionality for the automated test equipment 102 and may include any number of processors, micro-controllers, or other processing systems and resident or external memory for storing data and other information accessed or generated by the computing device. The processor 106 may execute one or more software programs which implement the techniques and modules described herein. The processor 106 is not limited by the materials from which it is formed or the processing mechanisms employed therein and, as such, may be implemented via semiconductor(s) and/or transistors (e.g., electronic Integrated Circuits (ICs)), and so forth.

The memory 108 is an example of non-transitory device-readable storage media that provides storage functionality to store various data associated with the operation of the computing device 102, such as the software program and code segments mentioned above, or other data to instruct the processor 106 and other elements of the electronic device 300 to perform the techniques described herein. Although a single memory 108 is shown, a wide variety of types and combinations of memory may be employed. The memory 108 may be integral with the processor 106, stand-alone memory, or a combination of both. The memory may include, for example, removable and non-removable memory elements such as Random Access Memory (RAM), Read Only Memory (ROM), Flash memory (e.g., a Secure Digital (SD) card, a mini-SD card, a micro-SD card), magnetic memory, optical memory, Universal Serial Bus (USB) memory devices, and so forth.

In an embodiment of the present disclosure, the system 100 includes a circuit design module 110, which represents functionality to design and/or test system on a chip integrated circuit devices 104. The module 110 is storable in the memory 108 and the executable by the processor 106. For example, an operator of the computing device 102 may provide parameters that are utilized by the module 110 to design and/or test integrated circuit designs. The computing device 102 may then generate one or more files including data that are utilized by semiconductor fabrication plants (e.g., fabs) to manufacture the devices of interest.

Once fabricated, as shown in FIG. 2, the system on a chip device 104 includes one or more scan chains 112 (e.g., scan chain circuitry) that facilitate testing of the system on a chip device 104. The scan chains 112 are connected to a respective compressor module 114 and a respective decompressor module 116. The compressor module 114 is configured to compress the ATPG test values received from the automatic test equipment 102, and the decompressor module 104 is configured to decompress the data output (e.g., data resulting from the compressed ATPG test values) from the scan chains 112. In an embodiment of the present disclosure, the scan chains 112 comprise one or more linking register structures 118 (see FIG. 2) that facilitate testing of the system on a chip device 104.

As shown in FIG. 2, the system on a chip device 104 includes multiple scan chains 112. For example, each system on a chip device 104 may include multiple scan chains 112 contained therein. As shown, the system on a chip device 104 includes multiple EDT groupings 120A, 120B (e.g., an EDT grouping) of scan chains 112 (e.g., each system on a chip includes multiple scan chain circuitry groupings). In some embodiments, the scan chain length of a first grouping 120A may be the same as the scan chain length of another grouping 120B within the system on a chip device 104. In other embodiments, the scan chain length of a first grouping 120A may not be the same as the scan chain length of another grouping 120B within the system on a chip device 104. A scan chain length may be defined as the number of storage devices (e.g., flip-flops) connected within a chain. Only two EDT groupings 120A, 120B are shown for illustrative purposes. However, it is understood that there may be more than two EDT groupings in accordance with teachings of the present disclosure.

Once fabricated, automatic testing equipment furnishes test signals representing scan patterns (e.g., testing patterns) to the system on a chip device 104 during operation. In one or more embodiments of the present disclosure, the test signals are based upon Wave Generation Language (WGL) patterns (e.g., ATPG patterns) loaded in the automatic testing equipment.

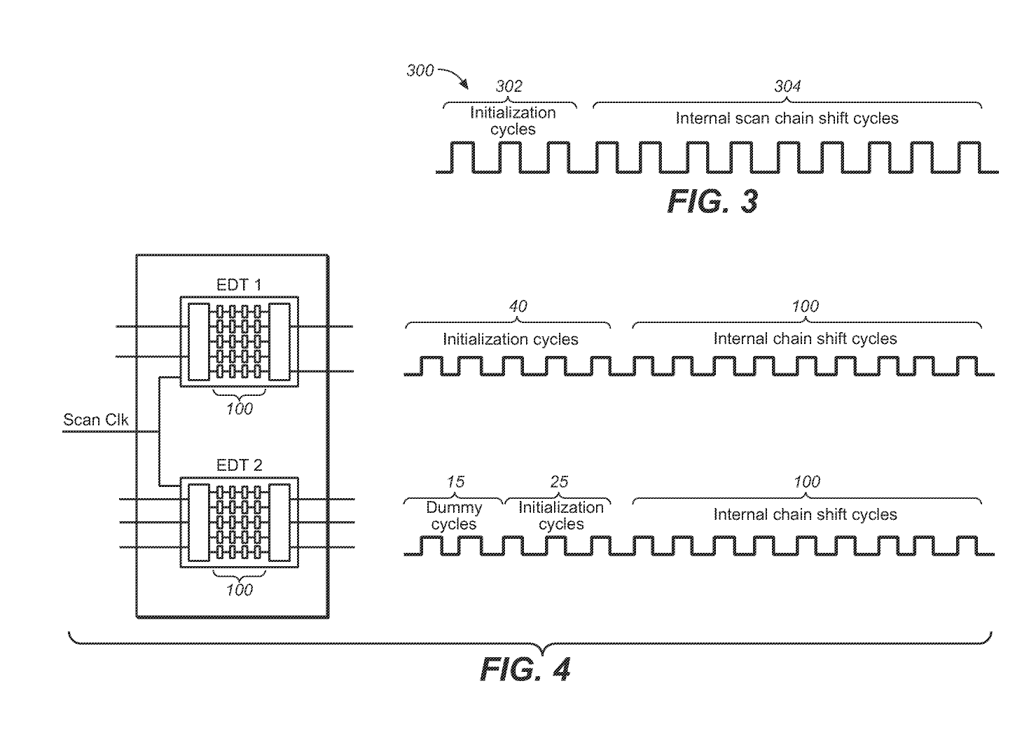

FIG. 3 illustrates example test signals 300 representing a scan pattern furnished to the system on a chip device 104. The test signals 300 comprise initialization cycles 302 and internal scan chain shift cycles 304. Thus, the total number of cycles that comprise a scan pattern is the initial cycles and the internal chain shift cycles. The initialization cycle for each grouping 120A, 120B may depend various parameters of each EDT grouping. For example, these parameters may include, but are not limited to: number of input channels, compression ratio associated with the EDT grouping, and/or a number of masking bits associated with each EDT grouping. Thus, the number of initialization cycles for each grouping 120A, 120B may differ depending upon the various parameters associated with the EDT groupings 120A, 120B. For example, a first EDT grouping 120A of scan chain circuitry may require a first number of initialization cycles, and a second EDT grouping 120B of scan chain circuitry may require a second number of initialization cycles.

As described above, each system on a chip device 104 includes multiple EDT groupings 120A, 120B. During conventional testing, when tested together at the system on a chip level, each EDT grouping would be subjected to the same number of clock cycles, which comprises the highest sum of initialization and internal chain shift cycle for the EDT groupings. However, this approach may result in increased tester time and/or tester costs since some EDT groupings are subjected to extra clock cycles. For example, as shown in FIG. 4, a first EDT grouping may require forty (40) initialization cycles and one hundred (100) internal chain shift cycles, and a second EDT grouping may require twenty-five (25) initialization cycles and one hundred (100) internal chain shift cycles. In this example, the second EDT grouping would be subjected to an extra fifteen (15) cycles (e.g., “dummy” cycles), which are unutilized by the second EDT grouping.

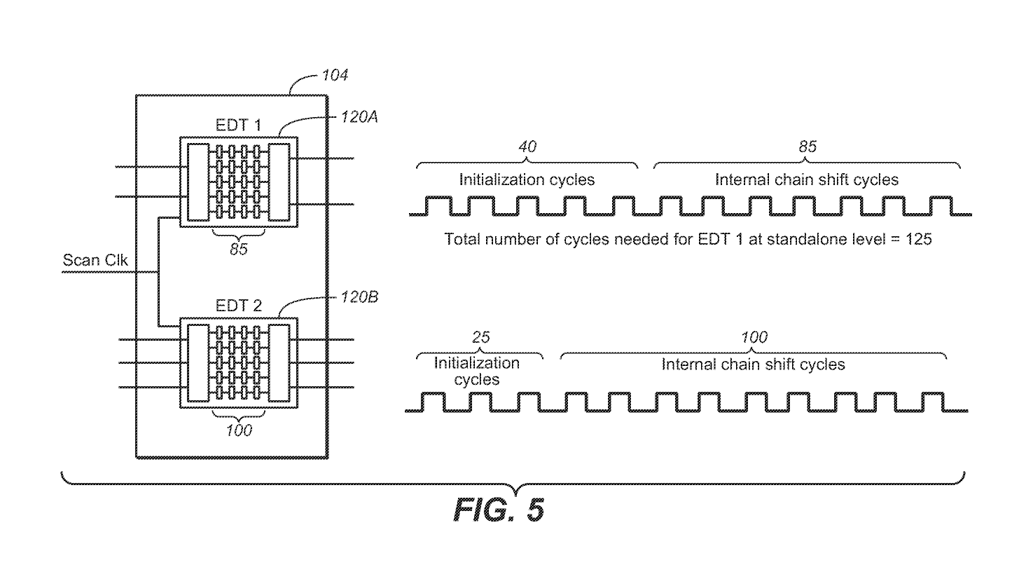

Based upon the number of initialization cycles and the total number of cycles required to test an EDT grouping, the module 110 is configured to determine a scan chain length of the EDT groupings 120A, 120B. For example, the computing device 102 receives one or more operational parameters indicating the number of initialization cycles for a first EDT grouping 120A and the number of initialization cycles for a second EDT grouping 120B. The operational parameters also include the total number of cycles for the first EDT grouping 120A and the second EDT grouping 120B. Based upon these parameters, the module 110 determines the scan chain length for the EDT groupings 120A, 120B such that total number of cycles of for a first signal for testing the first EDT grouping 120A and for a second signal for the second grouping 120B are the same. For example, as shown in FIG. 4, the first EDT grouping 120A may require a first signal having forty (40) initialization cycles and eighty-five (85) internal chain shift cycles, and the second EDT grouping 120B may require a second signal having twenty-five (25) initialization cycles and one hundred (100) internal chain shift cycles. In this example, the first signal and the second signal have the same total number of cycles. In this example, the scan chain length of the first EDT grouping 120A is determined to be eighty-five (85) and the scan chain length of the second EDT grouping 120B is determined to be one hundred (100) such that the sum of initialization cycles and the internal chain shift cycles remain the same across the EDT groupings within the system on a chip 104 (see FIG. 5). Based upon this determination, the computing device 102 generates a data file 122 including data for fabricating the system on a chip device 104.

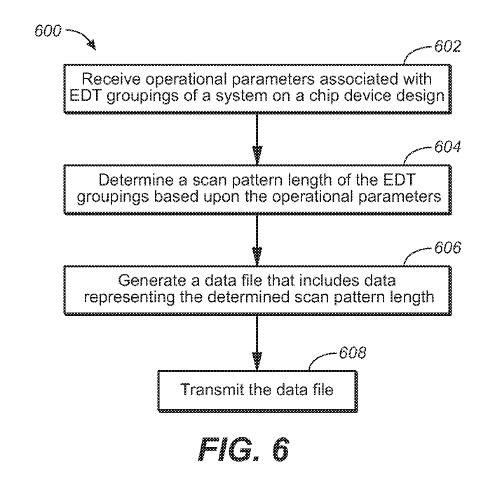

FIG. 6 illustrates an example method 600 for optimizing test time using embedded test compression cycle balancing. As shown, operational parameters associated with one or more EDT groupings of a system on a chip device are received at a computing device module (Block 602). As described above, the computing device 102 receives operational parameters for the EDT groupings 120A, 120B of a system on a chip device 104. In one or more embodiments, the operational parameters comprises, but is not limited to, the number of initialization cycles for a test signal for each grouping 120A, 120B, the number of internal chain shift cycles for a test signal each grouping 120A, 120B, and/or the total number of cycles for a test signal for each grouping 120A, 120B. A scan pattern length of the EDT groupings is determined (Block 604). In one or more embodiments of the present disclosure, the computing device 102 utilizes the operation parameters to determine the scan pattern length of each EDT grouping 120A, 120B within the system on a chip device 104. For example, the module 110 determines the scan chain length for the EDT grouping 120A and the scan chain length for the EDT grouping 120B such that the total number of cycles of respective test signals remain the same (e.g., the sum of the initialization and internal chain shift cycles remain the same across the EDT groupings 120A, 120B within the system on a chip device 104).

A data file is generated by the computing device (Block 606). As described above, the module 110 causes generation of a data file 122 that includes data representing the system on a chip device 104. For example, the data file 122 may include data utilized by a semiconductor fabrication facility to manufacture the system on a chip device 104 according to the above described techniques (e.g., manufacturing a system on a chip device 104 having scan chain lengths that such that the total number of cycles of respective test signals remain the same. The data file is transmitted to a semiconductor fabrication facility (Block 608). In one or more embodiments, the module 110 causes transmission of the data file 110 to a semiconductor fabrication facility.

Generally, any of the functions described herein can be implemented using hardware (e.g., fixed logic circuitry such as integrated circuits), software, firmware, manual processing, or a combination of these embodiments. Thus, the blocks discussed in the above disclosure generally represent hardware (e.g., fixed logic circuitry such as integrated circuits), software, firmware, or a combination thereof. In the instance of a hardware embodiment, for instance, the various blocks discussed in the above disclosure may be implemented as integrated circuits along with other functionality. Such integrated circuits may include all of the functions of a given block, system or circuit, or a portion of the functions of the block, system or circuit. Further, elements of the blocks, systems or circuits may be implemented across multiple integrated circuits. Such integrated circuits may comprise various integrated circuits including, but not necessarily limited to: a monolithic integrated circuit, a flip chip integrated circuit, a multichip module integrated circuit, and/or a mixed signal integrated circuit. In the instance of a software embodiment, for instance, the various blocks discussed in the above disclosure represent executable instructions (e.g., program code) that perform specified tasks when executed on a processor. These executable instructions can be stored in one or more tangible computer readable media. In some such instances, the entire system, block or circuit may be implemented using its software or firmware equivalent. In other instances, one part of a given system, block or circuit may be implemented in software or firmware, while other parts are implemented in hardware.

Although the subject matter has been described in language specific to structural features and/or process operations, it is to be understood that the subject matter defined in the appended claims is not necessarily limited to the specific features or acts described above. Rather, the specific features and acts described above are disclosed as example forms of implementing the claims.

What is claimed is:

1. An apparatus comprising:
a memory configured to store one or more modules;
a processor connected to the memory, the processor configured to execute the one or more modules to cause the processor to:
receive operational parameters associated with a first scan chain grouping circuitry and a second scan chain grouping circuitry of an integrated circuit design, the operational parameters comprising a characteristic number of initialization cycles of a first test signal selected for the first scan chain grouping circuitry, a characteristic number of initialization cycles of a second test signal selected for the second scan chain grouping circuitry, and a sum for a total number of cycles for the first test signal; and
determine a scan chain length for at least one of the first scan chain grouping circuitry or the second scan chain grouping circuitry based upon the operation parameters such that the total number of cycles of the first signal and the second signal are the same.

2. The system as recited in claim 1, wherein the operational parameters further comprise a characteristic number of internal shift scan cycles for the first signal and a characteristic number of internal shift scan cycles for the second signal.

3. The system as recited in claim 1, wherein the processor is further configured to execute the one or more modules to cause the processor to generate a data file including data representing the integrated circuit design including the first scan chain grouping circuitry and the second scan chain grouping circuitry.

4. The system as recited in claim 3, wherein the processor is further configured to execute the one or more modules to cause the processor to transmit the data file.

5. The system as recited in claim 1, wherein the integrated circuit design further comprises data representing a first compressor module configured to compress the first signal and a first decompressor module configured to generate a first output signal and a second compressor module configured to compress the second signal and a second decompressor module configured to generate a second output signal, wherein the first scan chain grouping circuitry is communicatively connected to the first compressor module and the first decompressor module and the second scan chain grouping circuitry is communicatively connected to the second compressor module and the second decompressor module.

6. The system as recited in claim 1, wherein respective scan chain circuitry comprises linking register structures.

7. The system as recited in claim 6, wherein at least one linking register structure comprises a flip-flop module.

8. An apparatus comprising:
a computing device including:
a memory configured to store one or more modules;
a processor connected to the memory, the processor configured to execute the one or more modules to cause the processor to:
receive operational parameters associated with a first scan chain grouping circuitry and a second scan chain grouping circuitry of an integrated circuit design, the operational parameters comprising a characteristic number of initialization cycles of a first test signal selected for the first scan chain grouping circuitry, a characteristic number of initialization cycles of a second test signal selected for the second scan chain grouping circuitry, and a sum for a total number of cycles for the first test signal;
determine a scan chain length for at least one of the first scan chain grouping circuitry or the second scan chain grouping circuitry based upon the operation parameters such that the total number of cycles of the first signal and the second signal are the same; and
generate a data file including data representing the integrated circuit design including the first scan chain grouping circuitry and the second scan chain grouping circuitry

9. The system as recited in claim 8, wherein the operational parameters further comprise a characteristic number of internal shift scan cycles for the first signal and a characteristic number of internal shift scan cycles for the second signal.

10. The system as recited in claim 8, wherein the processor is further configured to execute the one or more modules to cause the processor to transmit the data file.

11. The system as recited in claim 8, wherein the integrated circuit design further comprises data representing a first compressor module configured to compress the first signal and a first decompressor module configured to generate a first output signal and a second compressor module configured to compress the second signal and a second decompressor module configured to generate a second output signal, wherein the first scan chain grouping circuitry is communicatively connected to the first compressor module and the first decompressor module and the second scan chain grouping circuitry is communicatively connected to the second compressor module and the second decompressor module.

12. The system as recited in claim 8, wherein respective scan chain circuitry comprises linking register structures.

13. The system as recited in claim 12, wherein at least one linking register structure comprises a flip-flop module.

14. A method comprising:
receiving operational parameters associated with a first scan chain grouping circuitry and second scan chain grouping circuitry of an integrated circuit design, the operational parameters comprising a characteristic number of initialization cycles of a first test signal selected for the first scan chain grouping circuitry, a characteristic number of initialization cycles of a second test signal selected for the second scan chain grouping circuitry, and a sum for a total number of cycles for the first test signal; and
determining a scan chain length for at least one of the first scan chain grouping circuitry or the second scan chain grouping circuitry based upon the operation parameters such that the total number of cycles of the first signal and the second signal are the same

15. The method as recited in claim 14, wherein the operational parameters further comprises a characteristic number of internal shift scan cycles for the first signal and a characteristic number of internal shift scan cycles for the second signal.

16. The method as recited in claim 14, further comprising generating a data file including data representing the integrated circuit design including the first scan chain grouping circuitry and the second scan chain grouping circuitry.

17. The system as recited in claim 16, further comprising transmitting the data file to a semiconductor fabrication facility.

18. The system as recited in claim 14, wherein the integrated circuit design further comprises data representing a first compressor module configured to compress the first signal and a first decompressor module configured to generate a first output signal and a second compressor module configured to compress the second signal and a second decompressor module configured to generate a second output signal, wherein the first scan chain grouping circuitry is communicatively connected to the first compressor module and the first decompressor module and the second scan chain grouping circuitry is communicatively connected to the second compressor module and the second decompressor module.

19. The method as recited in claim 14, wherein respective scan chain circuitry comprises linking register structures.

20. The system as recited in claim 14, wherein at least one linking register structure comprises a flip-flop module.
